(19) United States
(12) Patent Application Publication
(10) Pub. No.: US 2003/0138117 A1
(43) Pub. Date: Jul. 24, 2003

(54) System and method for the automated detection, identification and reduction of multi-channel acoustical feedback

(76) Inventor: Eugene F. Goff, Macedon, NY (US)

Correspondence Address: GREENWALD & BASCH, LLP, 349 WEST COMMERCIAL STREET, SUITE 2490, EAST ROCHESTER, NY, 14445, US

(21) Appl. No.: 10/190,976

(22) Filed: Jul. 8, 2002

Related U.S. Application Data
(60) Provisional application No. 60/349,551, filed on Jan. 22, 2002.

(51) Int. Cl. H03G 5/00

(52) U.S. Cl. 381/103

(57) ABSTRACT

This invention relates generally to a system and method for the detection, identification and reduction of multi-channel acoustical feedback, and more particularly to a system and method wherein acoustical feedback is detected using electrical circuitry, identified via a control apparatus, depicted visually and selectively eliminated or suppressed in response to a user's input.

### CROSS REFERENCE

The following related application and patent are hereby incorporated by reference for their teachings:

“Multi-Channel Acoustic Feedback Detection, Identification, and Reduction System”, Eugene F. Goff; Provisional Application No. 60/349,551, filed Jan. 22, 2002.

“USER INTERFACE FOR THE CONTROL OF AN AUDIO SPECTRUM FILTER PROCESSOR”, Eugene F. Goff, U.S. Pat. No. 6,317,117, issued Nov. 13, 2001.

This invention relates generally to a system and method for the detection, identification and reduction of multi-channel acoustical feedback, and more particularly to a system and method wherein acoustical feedback is detected using electrical circuitry, identified via a control apparatus, depicted visually and selectively eliminated or suppressed in response to a user's input.

### BACKGROUND AND SUMMARY OF THE INVENTION

The present invention is directed to a system and a method for automatically detecting and identifying acoustic feedback on one or more audio channels input thereto. The system further includes a user interface for indicating the detection and identification information so as to allow a user to selectively suppress or eliminate such feedback.

Heretofore, a number of patents and publications have disclosed methods and components for the detection or suppression of feedback on audio signals, the relevant portions of which may be briefly summarized as follows:

U.S. Pat. No. 6,317,117 to Goff, issued Nov. 13, 2001, discloses a user interface control apparatus for controlling the filter parameters of audio spectrum equalizers, crossovers, and other filter processors.

The “OPERATOR's MANUAL; Model FD23 23, Channel Feedback Detector”, published as of 1996 by Goldline, West Redding, Conn., teaches an inexpensive means of detecting the frequency causing ringing in a sound system. The FD23 is described as having LEDs to display ISO third-octave frequencies from 80 Hz to 12.5 KHz that are detected as ringing.

In accordance with the present invention, there is provided an apparatus for the control of acoustic feedback tones in an audio system, comprising: an audio signal input source for generating an audio signal that is output to a loudspeaker; a feedback detector, responsive to the audio signal, for detecting feedback tones in the audio signal and creating control signals characterizing at least one aspect of the feedback tones; and display means, responsive to the control signals from the feedback detector, for indicating in a humanly perceptible manner the presence of detected feedback tones in the audio signal.

In accordance with another aspect of the present invention, there is provided a system for the control of acoustic feedback tones in an audio system, comprising: a plurality of audio signal input sources for generating audio signals on a plurality of audio channels; a channel selector for selecting at least one of the audio channels and the signal thereon for feedback control; a summing circuit for summing the audio signals, in the event that multiple channels are selected, to produce a composite audio signal; a band-pass filter for removing a range of frequencies from the composite audio signal to produce a filtered composite audio signal; a feedback detector, responsive to the filtered composite audio signal, for detecting feedback tones therein and creating control signals characterizing at least one aspect of the feedback tones; display means, responsive to the control signals from the feedback detector, for indicating, in a humanly perceptible manner, the characteristics of detected feedback tones in the audio signal; a plurality of equalizers for receiving the audio signal from the plurality of audio channels and producing equalized audio signals, wherein the operation of at least one of said equalizers is responsive to control signals generated by said feedback detector; a mixer for receiving the equalized audio signals and summing the equalized audio signals to produce a processed audio signal, wherein the operation of the mixer is responsive to control signals generated by said feedback detector; and a loudspeaker for receiving the processed audio signal and converting the signal to an acoustic signal.

In accordance with yet another aspect of the present invention, there is provided a method for the control of acoustic feedback tones in an audio system, comprising the steps of: selecting at least one channel in an audio processing system for which feedback control is desired; filtering and summing audio signals from the selected channels to produce a composite audio signal; searching, within the composite audio signal, for feedback tones, and if detected analyzing the composite audio signal to determine the characteristic of the feedback tones; generating control signals and data indicating the characteristics of the feedback tones; and displaying at least one of the characteristics in a human perceptible form.

One aspect of the present invention deals with a basic problem in audio systems—the possibility of feedback being generated under certain circumstances or situations. This aspect is further based on the discovery of a technique that alleviates this problem, and for the potential of a user-interface to display or depict the presence of feedback tones to an audio technician. Such a system may automatically correct for such tones in order to suppress them, or may simply provide an “alarm” to indicate their presence to the technician. As a result of the invention, the detection and elimination of feedback tones in audio system will be improved.

### BRIEF DESCRIPTION OF THE DRAWINGS

FIG. 1 is a schematic block diagram of an embodiment of the present invention;

FIGS. 2 and 3 are exemplary illustrations of alternative interface displays in accordance with aspects of the present invention;

FIG. 4 is a flow chart illustrating the general steps accomplished by a system operating to implement aspects of the present invention;

FIGS. 5 and 6 are block diagrams respectively depicting integrated and networked configurations as alternative embodiments of the present invention; and

FIG. 7 is an exemplary illustration of a user interface, including user controls, in accordance with an aspect of the present invention.

The present invention will be described in connection with a preferred embodiment, however, it will be understood that there is no intent to limit the invention to the embodiment described. On the contrary, the intent is to cover all alternatives, modifications, and equivalents as may be included within the spirit and scope of the invention as defined by the appended claims.

### DESCRIPTION OF THE PREFERRED EMBODIMENT

For a general understanding of the present invention, reference is made to the drawings. In the drawings, like reference numerals have been used throughout to designate identical elements.

As used herein, the term “feedback tone” or “feedback signal” is intended to include those signals produced by a positive electro-acoustical feedback loop that results when an audio amplification system, including a microphone or other electro-acoustic input device and loudspeaker or similar electro-acoustic transducer output device, has a total gain greater than or equal to one, resulting in an uncontrolled self-oscillating system. Feedback tones are generally characterized as having a highly periodic, sinusoidal waveform with low harmonic frequency energy, and typically a high fundamental amplitude.

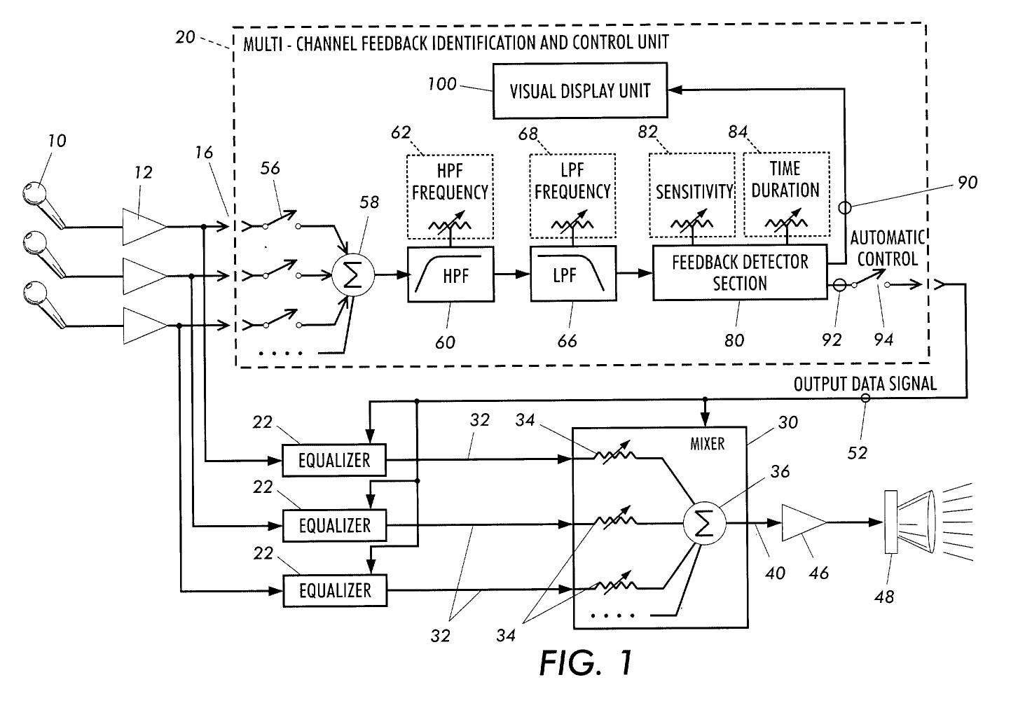

Referring to FIG. 1, there is displayed a schematic diagram for an exemplary embodiment of the present invention. One or more microphones or other audio signal input sources 10 are fed into preamplifiers 12 to amplify the audio signals to nominal line voltage levels, approximately 1.0 volt. The preamplifiers feed the line voltage audio signals to the audio input channels 16 of the multi-channel feedback identification and control unit 20. The line voltage audio signals also feed into one or more audio equalizers 22 to equalize (filter) the audio signals. The output signals of the equalizers feed into audio signal inputs of the audio mixing console 30. The audio mixing console, as is known in the art contains two or more audio input channels 32, two or more input channel level controls 34 (one for each audio input channel), and a summing network 36 that produces an audio output signal on line 40. The audio output signal from the mixing console, line 40, feeds into the audio input of the power amplifier 46 which, in turn, amplifies the audio signal to a higher voltage and current level to drive one or more loudspeakers 48.

As illustrated in the figure, the multi-channel feedback identification and control unit 20 generates an output data signal on line 52 that provides control signals used to control the audio equalizer(s) 22 and the audio mixer 30. The multi-channel feedback identification and control unit 20 receives one or more audio inputs 16 which, as noted above, typically have a nominal input voltage level of 1.0 volts. The audio input signals preferably pass through series input channel selection switches 56 that allow an operator to select one or more input signals for the feedback identification and control system to operate on. When input channel selection switches 56 are in a closed-circuit position, the corresponding audio input signals are passed into the summing network 58 of the multi-channel feedback identification and control unit, which adds the audio signals together to produce a composite audio signal.

Subsequently, the composite audio signal output from the summing network 58 is filtered to remove high and low frequency components. More specifically, the signal is input to a high-pass filter 60 to filter out low frequency audio components of the signal that are below the high-pass filter's corner frequency (−3 dB frequency). In a preferred embodiment, the high-pass filter 60 contains an operator-adjustable, High-pass frequency control 62. The audio output signal from the high-pass filter is then, in turn, fed as an input to a low-pass filter 66, which filters out the high frequency components of the audio signal; those frequencies that are above the low-pass filter's corner frequency. The low-pass filter contains an operator-adjustable Low-pass frequency control 68. The purpose of the high-pass filter and low-pass filter is to allow an operator to filter the low and high frequency signal components respectively, from the composite audio signal, and therefore limit the composite audio signal's frequency spectrum before it is fed into the feedback detector section 80.

Continuing with FIG. 1, feedback detector section 80 contains a composite audio signal input, which operates at a nominal input level of 1.0 volt. The feedback detector section contains an operator-adjustable sensitivity control 82, as one user control means that allows control of the feedback detector threshold at which the detector decides that a tone is a feedback signal and not an audio program signal. The feedback detector section also contains a second user control in the form of an operator-adjustable time duration control 84 that allows control of the feedback detector's minimum time at which it decides that a tone is a feedback signal and not an audio program signal. In other words, the feedback must be present for the minimum time before there is indication that the audio signal contains feedback. The feedback detector section also generates a data output signal 90 that feeds a visual display unit 100. This data output signal may be analog, digital or a combination of both and provides information to the visual display unit about any acoustic feedback signals detected by feedback detector section.

The feedback detector section also generates an automatic control signal output on line 92. This automatic control signal is fed to a series automatic control switch 94 that enables the operator to switch the automatic control signals on, allowing them to pass through the switch to line 52. As previously described, this automatic output control signal may be analog or digital and preferably includes control signals for the audio equalizers 22 and the audio mixer 30 to automatically change audio filter parameters in the equalizer(s), and/or change audio signal levels in the audio mixer in a way which reduces or suppresses the acoustic feedback tones.

Having described the general operation and components of an embodiment of the present invention, attention is now turned to the specific functionality of the feedback detector section 80 of FIG. 1. The main function of the feedback detector section 80 is to detect the presence of any acoustic feedback tones that may be present in the filtered composite audio signal, and then to measure the frequency, amplitude, and time duration of the feedback tones. Feedback tones are produced by a positive electro-acoustical feedback loop that results when an audio amplification system, including the microphone and loudspeaker, has a total gain greater than or equal to one, thereby resulting in an uncontrolled self-oscillating system. Feedback tones are characterized as having a sinusoidal waveform that is highly periodic, with low harmonic frequency energy and typically having a high fundamental amplitude.

The present invention contemplates that many different methods may be used to discriminate unwanted feedback tones from the desired audio program. The audio signal can be filtered in the time domain into frequency bands, then analyzed to search for frequency bands with high amplitude signals with correspondingly low harmonic frequency band amplitudes. Also, the periodicity of the audio signal can be analyzed in the time domain to search for highly periodic signals. Furthermore, a synthesized sine wave signal can be subtracted from the audio signal and then can sweep in frequency while detecting minimum combined signal energy.

Alternatively, the audio signal can be analyzed in the frequency domain using a variety of time-to-frequency domain transforms, which are well known in electrical signal processing publications. The spectrum characteristics of the audio signal can then be analyzed in the frequency domain such as searching for amplitudes above a given threshold or searching for amplitudes that have correspondingly low harmonic frequency amplitudes.

Several patents describe different methods and apparatus for suppressing unwanted acoustic feedback. U.S. Pat. Nos. 5,999,631, 5,245,665, 5,717,772, 5,533,120, 4,783,818, each being expressly incorporated herein in their entirety by reference, all disclose some form of a feedback detector subcomponent. The patents, however, do not disclose or describe operator-adjustable controls channel selection, high-pass filter frequency, low-pass filter frequency, feedback detection sensitivity, or minimum feedback time duration as have been incorporated within the present invention. The patents also do not teach feedback signal identification and display methods and apparatus contained as described herein.

In one particular embodiment, the present invention includes a detector section that incorporates a Hartley (time-to-frequency) transform using a multi-rate sampling method, followed by a combination of fundamental-to-harmonic amplitude comparisons and absolute amplitude minimums within frequency sub-bands. Part of the technique may be implemented in a manner similar in nature, to aspects of the detection described in U.S. Pat. No. 5,245,665, which uses a Fast-Fourier Transform (FFT) with multi-rate sampling and fundamental-to-harmonic amplitude comparisons.

More specifically, the present invention may employ the following signal processing steps performed by hardware components in a preferred detector section:

1. Band-split, preferably using broad band-pass filters, the audio spectrum into three bands with differing frequency ranges—low, mid, and high frequency bands;

2. Perform a Fast Hartley Transform (time-to-frequency transformation) on each of the three bands;

3. Pick the largest signal amplitude in each of the frequency spectrums produced by Step 2.

4. Compute the summation of the second and third harmonic signal amplitudes for each of the three signals in Step 3; and

5. Determining if any of the three amplitudes picked in Step 3 are greater than their associated second and third harmonic summations (computed in Step 4) multiplied by a predetermined factor, and if so then feedback is assumed to have been detected.

The predetermined factor in Step 5 may be a preset value or may be adjustable as a function of the sensitivity level set with operator-adjustable sensitivity control 82. It will be further appreciated by those skilled in the art of audio signal processing that the number of bands may be altered, as may be the method in which the signals are processed or the criteria used to identify the presence of feedback.

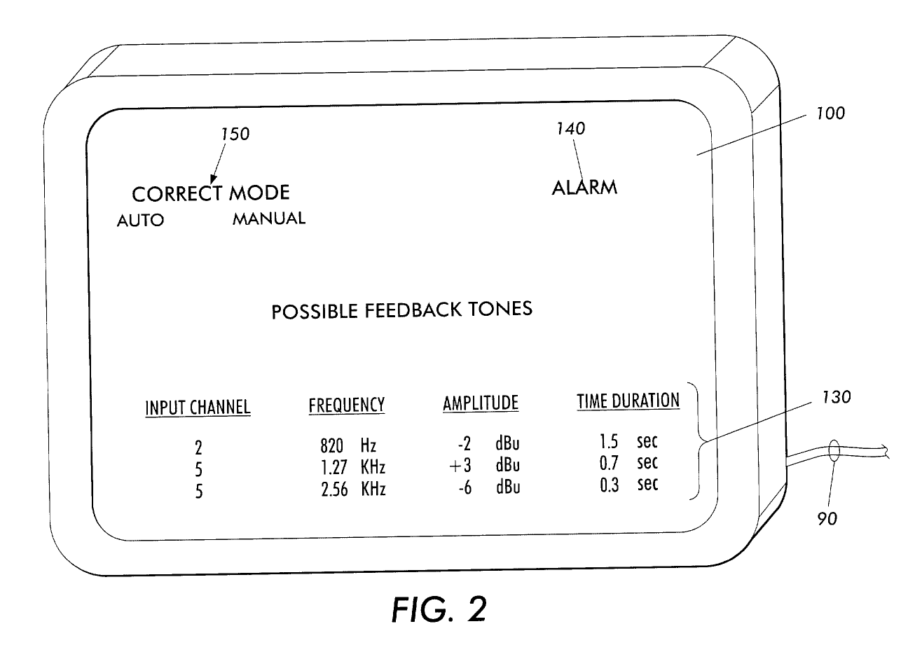

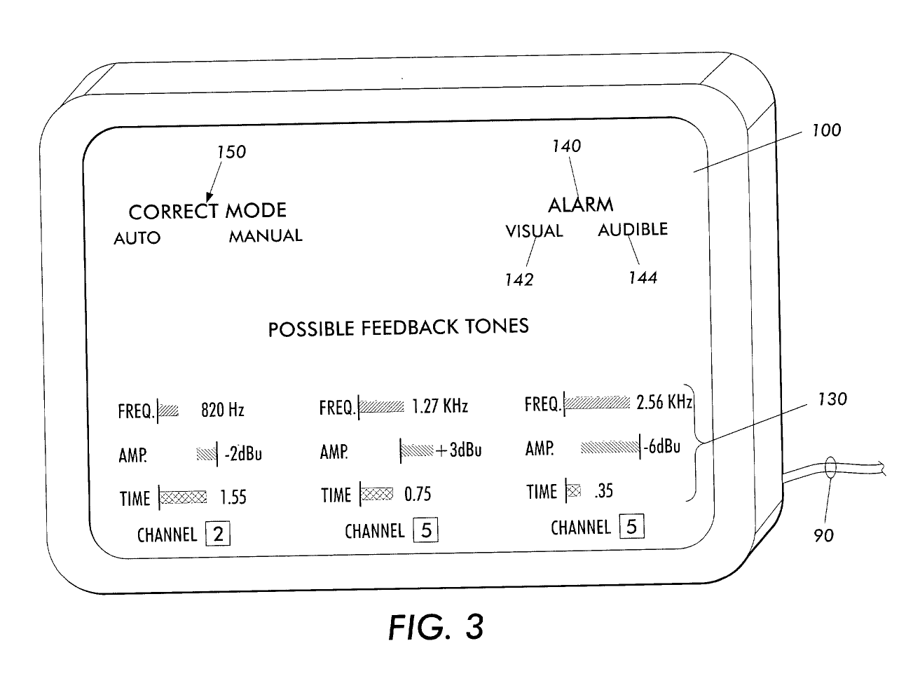

Having described in some detail the operation of various components of the present invention, attention is now turned to FIGS. 2 and 3, where there is depicted an exemplary user-interface that may be used in accordance with an aspect of the present invention. In particular, the visual display unit 100 may be a text character display (FIG. 2) or a graphical display (FIG. 3) that displays the acoustic feedback information to the operator for viewing. While numerous visual display types are possible, the present invention contemplates the use of a video monitor or a liquid-crystal or active-matrix type display as may be found, for example, on various pieces of computer equipment and hand-held devices. For ease of display and use, it is further contemplated that a display such as that depicted in FIG. 2 may be a windowed region on a computer display, wherein underlying display software updates the information in real time. Examples of such functionality are well known. For example, the display of various audio channel output levels and frequencies are provided in software available for use on MS-Windows based computer systems.

As illustrated in FIGS. 2 and 3, the visual display information may show, one or more of the following pieces of information as detected by the feedback detector section: the feedback tones'input channel number(s), the corresponding feedback frequency(s) measured in Hertz, the corresponding amplitude(s) measured in volts or decibels, and the corresponding feedback time duration(s) measured in seconds. More specifically, visual display unit 100 may depict the feedback information in a table format 110, where the channel, feedback frequency, amplitude and time are represented as specific values. Moreover, it is contemplated that the information may be updated over time, so that an initial indication of possible feedback may be confirmed and eliminated by the user of the system (e.g., in manual correction mode).

In an alternative embodiment for the present invention, the visual display is provided with a means for displaying the relevant data in a graphical form in region 130. Specifically, each of the pieces of information may be displayed using a bar graph, so that the user is able to perceive relative information more easily. Although depicted as bar graphs, it will be appreciated that other forms of graphical output may be utilized, and that the color, shape, size and format of the display components may be altered.

In the embodiments of the visual display depicted in FIGS. 2 and 3, it is also contemplated that when the feedback control system detects possible feedback tones, an alarm indicator 140 is energized or lit to provide a visual signal to the user. In conjunction with the visual indicator, it is also possible for the “ALARM” indicator to include an audible signal to a user in the event the user's attention is not directed to the system. The user's selection of the visual and/or audible alarms may be further indicated on the visual display as depicted, for example, in FIG. 3, indicators 142 and 144.

It is further contemplated that the visual display 100 includes an indication of the correction mode in which the system is operating. For example, correction mode indicator region 150 includes an identifier “CORRECT MODE” and would have one of two possible settings highlighted or “lit” to indicate the mode. As described above, the feedback control system may be operated in a manual mode, where the user is shown data on possible feedback, but where the user must initiate any correction. For example, were the “MANUAL” mode highlighted, when possible feedback is detected by the system and displayed to the user, the user might change a slider control on one of the equalizers 22 or change a volume control on the mixer 30.

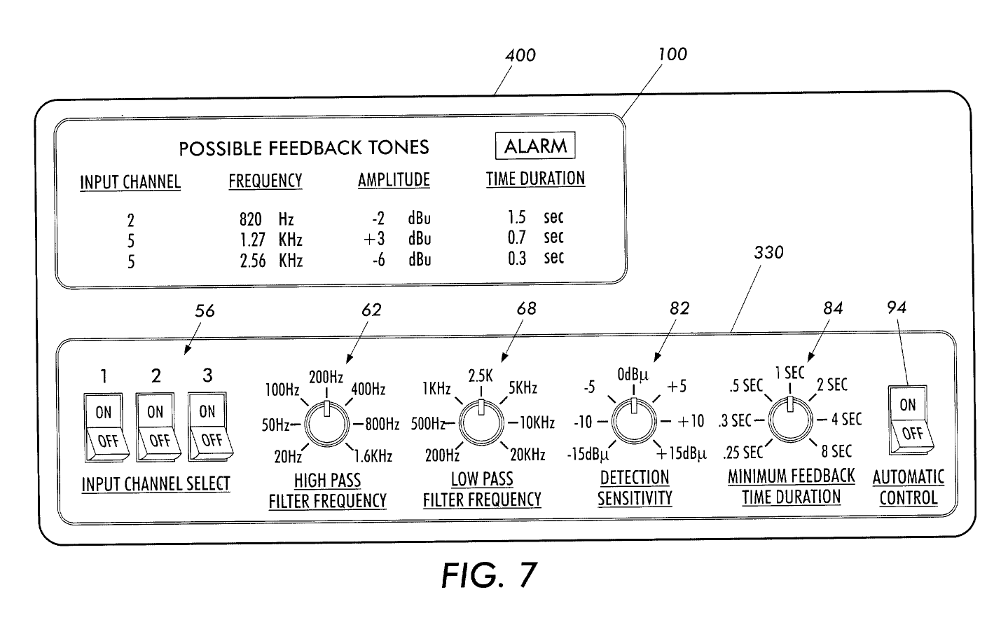

In the alternative mode, the “AUTO” indicator in region 150 is highlighted and while the detection in formation is displayed to a user, the system automatically eliminates the feedback by sending output data control signals to electronically controlled equalizers 22 and/or electronically controlled mixer 30. Lastly, it is further contemplated that the user may switch between modes of operation so as to be able to take over control during a set-up phase, etc. where the various adjustments of the feedback control system are being made. As described with respect to FIG. 7, a user interface may be employed to both display the detected ringing tones to a user and to enable the user to adjust control parameters on the feedback detection and identification apparatus.

Although not depicted, it is further contemplated that a visual display, such as display 100 may be computer-generated and employed to enable the user to adjust/define or “program” the various variable settings indicated above, where input from the user in the form of digital data is acquired from a computer mouse/menu, keyboard or other computer input device to produce the required inputs to the system (e.g., sensitivity).

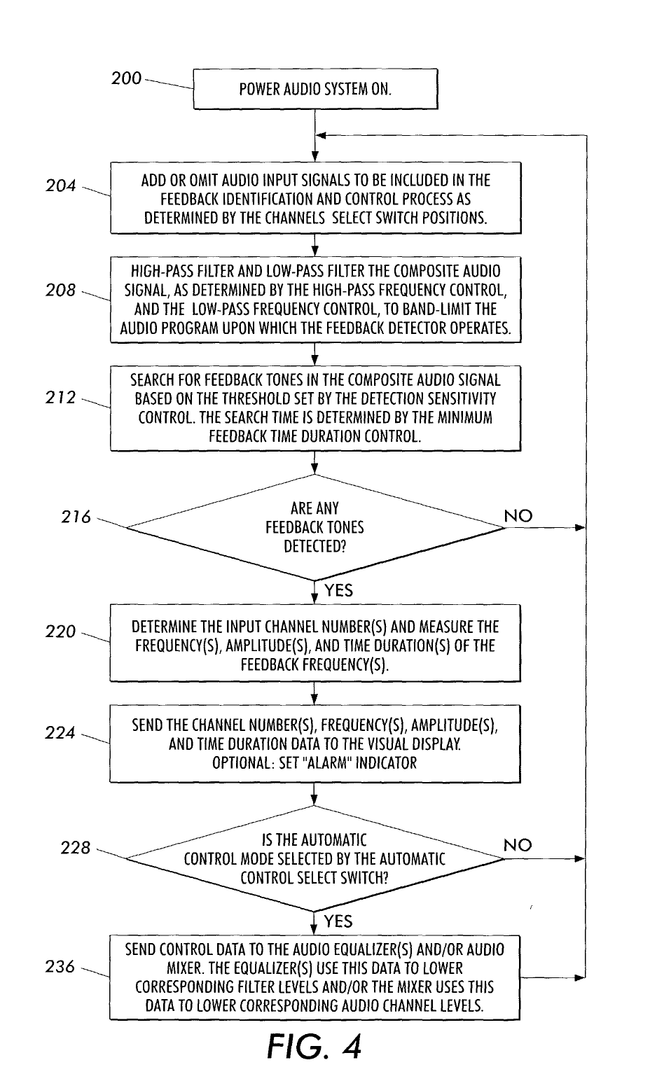

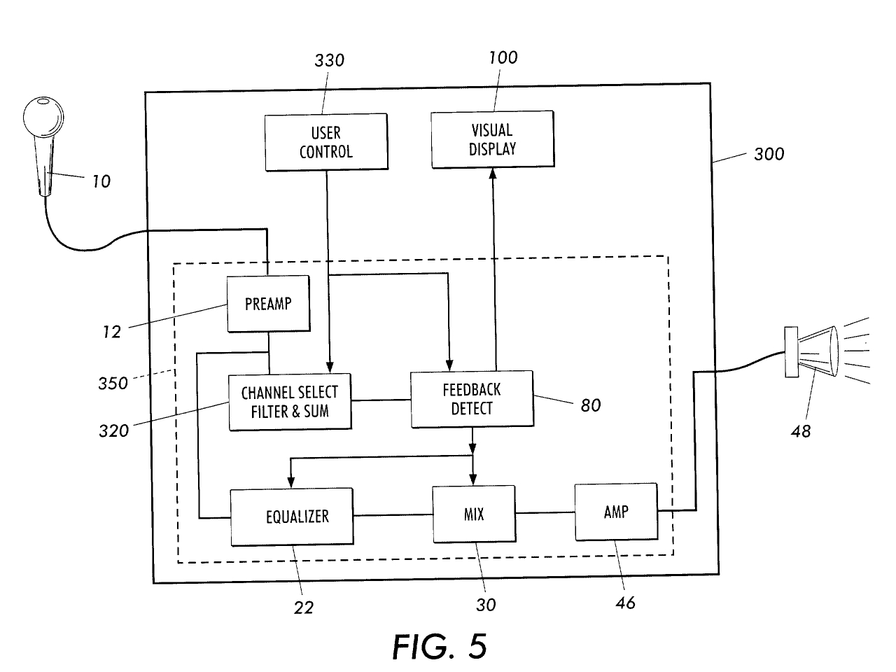

Turning now to FIG. 4, depicted therein is a flowchart that illustrates, generally, the various process steps performed in accordance with aspects of the present invention. Step 200 indicates that the process begins when the unit is powered on, and runs in a continuous loop until the unit is powered off (not shown). Next, at step 204, audio input signals to be included in the feedback identification and control process are added or omitted, as determined by the channels select switch (56) positions. At step 208, the audio signals on the channels are filtered and summed to produce the composite audio signal. As described above, the frequencies of the filters may be adjusted to band-limit the audio program upon which the feedback detector of the present invention operates.

Having created the composite audio signal, step 212 then passes the signal to the detector 80, where the detector searches for feedback tones in the composite audio signal based on the threshold set by the detection sensitivity control. The search time is determined by the minimum feedback time duration control. Next, text step 216 determines whether any feedback tones were detected, based upon the output from the detector. If not, processing continues at step 204. Otherwise, when possible feedback tones are detected, the process continues at step 220. At step 220, detector 80 analyzes the signals, in accordance with the signal processing operations set forth above, to determine the input channel number(s) and measure the frequency(s), amplitude(s), and time duration(s) of the feedback frequency(s). Based upon the analysis, the detector may then generate control signals and data that indicate the channel number(s), frequency(s), amplitude(s), and time duration of the feedback for representation on visual display 100, as set forth in step 224.

Next, at step 228, a determination is made as to whether the automatic correction feature of the present invention has been enabled (switch 92), and if not, then no output data control signals are generated. If auto correction is enabled, of if in response to an alarm indicating possible feedback, a user enables suppression of the feedback tones, the process continues at step 236, where control data is sent to the audio equalizer(s) and/or audio mixer, and the equalizer(s) use this data to lower corresponding filter levels and/or the mixer uses this data to lower corresponding audio channel levels to eliminate the feedback. Subsequently, the process continues in a repetitive loop to enable the detection and/or suppression of subsequent feedback tones.

Having described an apparatus and method in accordance with the present invention, attention is now turned to various alternative embodiments of the present invention which will be briefly described below and which are generally indicated in the associated figures. In one embodiment, a single, fully-integrated unit 300 contains the entire system consisting of audio processing and feedback detection circuitry 350 including audio signal preamplification 12, channel selection and summing 320, composite signal filtering 320, the feedback detector section 80, the feedback detector controls 330 (e.g., channel selection, frequency cutoffs, sensitivity, time, etc.), a text or graphical display 100, automatic control selection switch (part of user controls 330), signal equalization 22, mixing 30, and loudspeaker amplification 46. The unit may be a single or multi-channel unit.

In the embodiment of FIGS. 1-3, a single unit contains the channel selection and summing, composite audio filtering, feedback detector section, feedback detector controls, and a text or graphical display as described. Moreover, other devices external to the unit may implement audio signal amplification, equalization, and mixing, yet in response to signals from the feedback detector (assuming automatic control is enabled). This unit may be a single or multi-channel unit. Further, as noted previously, such an embodiment could be implemented on a standard personal computer with additional plug-in peripheral circuit cards.

In yet another embodiment, it is envisioned that the feedback detector alone may be used, where a single unit contains just the feedback detector section and the feedback detector controls. Audio signal preamplification, switching, summing, filtering, equalization, mixing, and power amplification is implemented by other devices external to the unit. In such an embodiment, it is contemplated that the visual display unit may be an external CRT display or an LCD display as commonly used in personal computers or hand-held devices. This unit may also be a single or multi-channel unit, as well as one that might interface, as a peripheral, to a standard personal computer.

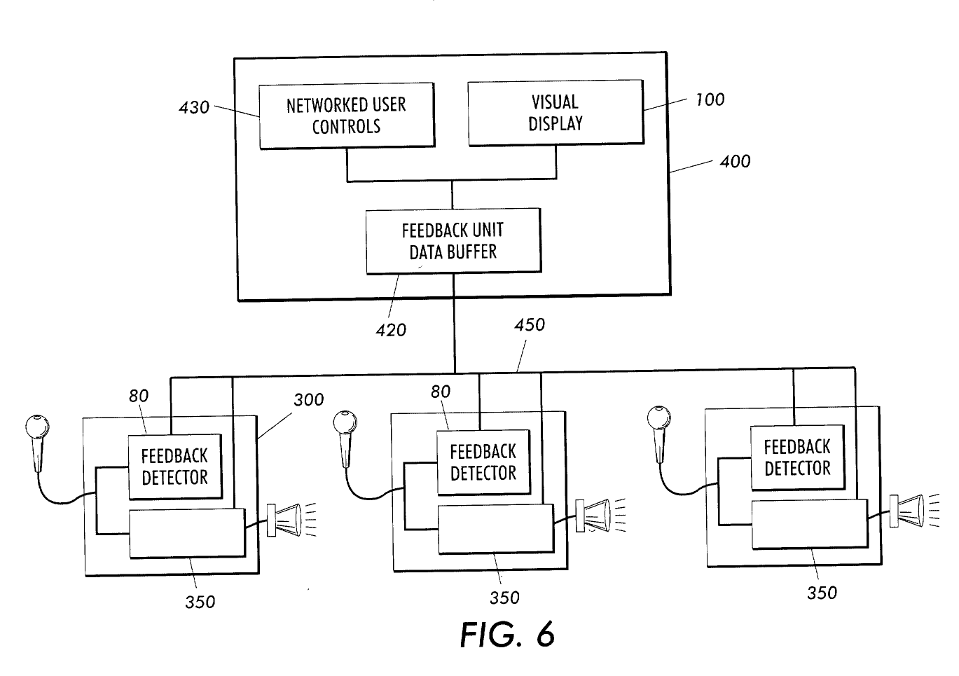

Lastly, it is contemplated that for complex audio requirements, aspects of the present invention may be networked to eliminate redundancy and improved user functionality. In the embodiment of FIG. 6, a single unit contains a feedback detector data buffering section 420 in which multiple feedback detector units 80 may be connected to each other via a computer network interface (e.g., SCSI, TCP/IP, wireless, etc.). Each feedback detector unit 80 may be a single or multiple channel unit, and the data from/to the unit would flow via a network so that a central “station” 400 may provide a control interface 430 and a visual display 100 of the various feedback detection devices and associated audio channels. The feedback detector network contains at least one visual display 100 and one control interface 430 for system operation. The visual display and user interface could be a CRT monitor, keyboard, mouse, or other common display and user control devices used with personal computers.

Turning lastly to FIG. 7, depicted therein is an exemplary illustration of a user interface, including user controls, in accordance with an aspect of the present invention. In particular, the interface 400 may include a display component 100 as well as controls 330. Controls 330 may further include a plurality of switches 56 that may be used to select the input channels for the feedback detector to monitor. In addition to the switches, the controls may include adjustments knobs or sliders (in the form of a variable resistor) for user-adjustable parameters of the feedback detection apparatus, including the high-pass filter frequency 62, the low pass filter frequency 68, the detection sensitivity 82 and the time duration 84. Similarly, as previously noted with respect to FIG. 1, switch 94 may be employed to control whether the automatic feedback control is enabled or disabled.

In recapitulation, the present invention is a method and apparatus for the detection, identification and reduction of multi-channel acoustical feedback, and more particularly to a system and method wherein acoustical feedback is detected using electrical circuitry, identified via a control apparatus, depicted visually and selectively eliminated or suppressed in response to a user's input.

It is, therefore, apparent that there has been provided, in accordance with the present invention, a method and apparatus for the detection, identification, display and suppression of audio feedback on one or more audio channels. While this invention has been described in conjunction with preferred embodiments thereof, it is evident that many alternatives, modifications, and variations will be apparent to those skilled in the art. Accordingly, it is intended to embrace all such alternatives, modifications and variations that fall within the spirit and broad scope of the appended claims.

1. An apparatus for the detection, identification and control of acoustic feedback tones in an audio system, comprising:
an audio signal input source for generating an audio signal that is output to a loudspeaker;
a feedback detector, responsive to the audio signal, for detecting feedback tones in the audio signal and creating control signals characterizing at least one aspect of the feedback tones;
user control means for adjusting at least one input parameter of the feedback detector; and
display means, responsive to the control signals from the feedback detector, for indicating in a humanly perceptible manner the characteristics of detected feedback tones in the audio signal.

2. The apparatus of claim 1, further comprising means for suppressing the feedback tones.

3. The apparatus of claim 2, wherein said means for suppressing the feedback tones includes an equalizer, responsive to the control signals, to adjust audio filtering parameters of the equalizer in order to suppress the feedback tones.

4. The apparatus of claim 2, wherein said means for suppressing the feedback tones includes a mixer, responsive to the control signals, to change audio signal levels of the audio signal in a way that suppresses the acoustic feedback tones.

5. The apparatus of claim 2, wherein said means for suppressing the feedback tones includes an equalizer and a mixer, both responsive to the control signals, wherein the equalizer automatically changes audio filter parameters, and the mixer automatically changes audio signal levels to suppress the acoustic feedback tones.

6. The apparatus of claim 1, wherein the display means is a two-dimensional visual display suitable for depicting at least one of the characterized aspects of the feedback tones.

7. The apparatus of claim 6, wherein at least one of the characterized aspects of the feedback tones is selected from the group consisting of:
input channel;
frequency;
amplitude; and
time duration.

8. The apparatus of claim 6, wherein the two-dimensional visual display depicts at least one of the characterized aspects of the feedback tones in a textual manner.

9. The apparatus of claim 6, wherein the two-dimensional visual display depicts at least one of the characterized aspects of the feedback tones in a graphical manner.

10. The apparatus of claim 1, wherein the display means includes a visual alarm indicating the presence of detected feedback tones.

11. The apparatus of claim 1, wherein the display means is is accompanied with an audible alarm indicating the presence of detected feedback tones.

12. The apparatus of claim 2, wherein said means for suppressing feedback tones operates automatically upon detection of feedback tones by said feedback detector.

13. The apparatus of claim 12, wherein the automatic operation of the means for suppressing feedback tones may be enabled and disabled by a user.

14. The apparatus of claim 1, wherein the feedback detector is responsive to user-adjustable input parameters set using the user control means for adjusting at least one input parameter of the feedback detector.

15. The apparatus of claim 14, wherein the user-adjustable input parameter of the feedback detector is a threshold at which the feedback detector determines that a tone is a feedback signal and not an audio program signal.

16. The apparatus of claim 14, wherein the user-adjustable input parameter of the feedback detector is a time duration that controls the minimum time at which the feedback detector determines that a tone is a feedback signal and not an audio program signal.

17. The apparatus of claim 14, further including at least one band-pass filter to eliminate a range of frequency components from the audio signal input to the feedback detector.

18. The apparatus of claim 17, wherein a user may adjust the range of frequency components eliminated.

19. The apparatus of claim 1, wherein the feedback detector processes the audio signal using a Hartley transform and a multi-rate sampling method, followed by a combination of fundamental-to-harmonic amplitude comparisons and absolute amplitude minimums within frequency sub-bands.

20. The apparatus of claim 14, wherein the user-adjustable input parameter of the feedback detector is a channel selection switch, such that the feedback detector operates only on input signals on a selected channel.

21. A system for the detection, identification and control of acoustic feedback tones in an audio system, comprising:
a plurality of audio signal input sources for generating audio signals on a plurality of audio channels;
a channel selector for selecting at least one of the audio channels and the signal thereon for feedback control;
a summing circuit for summing the audio signals, in the event that multiple channels are selected, to produce a composite audio signal;
a band-pass filter for removing a range of frequencies from the composite audio signal to produce a filtered composite audio signal;
a feedback detector, responsive to the filtered composite audio signal, for detecting feedback tones therein and creating control signals characterizing at least one aspect of the feedback tones;
display means, responsive to the control signals from the feedback detector, for indicating, in a humanly perceptible manner, the characteristics of detected feedback tones in the audio signal;
a plurality of equalizers for receiving the audio signal from the plurality of audio channels and producing equalized audio signals, wherein the operation of at least one of said equalizers is responsive to control signals generated by said feedback detector;
a mixer for receiving the equalized audio signals and summing the equalized audio signals to produce a processed audio signal, wherein the operation of the mixer is responsive to control signals generated by said feedback detector; and
a loudspeaker for receiving the processed audio signal and converting the signal to an acoustic signal.

22. The system of claim 21, wherein the display means is a two-dimensional visual display suitable for depicting at least one characteristic of the detected feedback tones.

23. The system of claim 22, wherein at least one of the characteristics of the detected feedback tones is selected from the group consisting of:
input channel;
frequency;
amplitude; and
time duration.

24. The system of claim 21, wherein the display means includes a visual alarm indicating the presence of detected feedback tones.

25. The system of claim 21, wherein the display means is accompanied by audible alarm indicating the presence of detected feedback tones.

26. The system of claim 21, wherein the feedback detector is responsive to user-adjustable input parameters.

27. The system of claim 26, wherein the user-adjustable input parameter is a threshold at which the feedback detector determines that a tone is a feedback signal and not an audio program signal.

28. The system of claim 26, wherein the user-adjustable input parameter is a time duration that controls the minimum time at which the feedback detector determines that a tone is a feedback signal and not an audio program signal.

29. The apparatus of claim 26, further including at least one band-pass filter to eliminate a range of frequency components from the audio signal input to the feedback detector.

30. The apparatus of claim 29, wherein a user may adjust the range of frequency components eliminated.

31. The apparatus of claim 26, wherein the user-adjustable input parameter of the feedback detector is a channel selection switch, such that the feedback detector operates only on input signals on a selected channel.

32. A networked system for the detection, identification and control of acoustic feedback tones on a multi-channel audio system, comprising:
a plurality of audio signal input sources for generating audio signals;
a plurality of feedback detectors, associated with said audio input sources and responsive to the audio signals, for detecting feedback tones in the audio signal and creating control signals characterizing at least one aspect of the feedback tones;
a central control station, in communication with the various feedback detectors and capable of receiving the control signals therefrom, said control station including
display means, responsive to the control signals, for indicating in a humanly perceptible manner the characteristics of detected feedback tones in the audio signal, and
controls to enable a user at the control station to modify the parameters of at least one feedback detector;
means for suppressing the feedback tones in the audio signals from the audio input sources and producing a processed audio signal; and
a loudspeaker for outputting the processed audio signal.

33. The networked system of claim 32, wherein the display means is a two-dimensional visual display suitable for depicting at least one characteristic of the detected feedback tones.

34. The networked system of claim 33, wherein at least one of the characteristics of the detected feedback tones is selected from the group consisting of:
input channel;
frequency;
amplitude; and
time duration.

35. The networked system of claim 32, wherein the display means includes a visual alarm indicating the presence of detected feedback tones.

36. The networked system of claim 32, wherein the display means is accompanied by an audible alarm indicating the presence of detected feedback tones.

37. The networked system of claim 32, wherein at least one feedback detector is responsive to user-adjustable input parameters.

38. The networked system of claim 37, wherein the user-adjustable input parameter is a threshold at which the at least one feedback detector determines that a tone is a feedback signal and not an audio program signal.

39. The networked system of claim 37, wherein the user-adjustable input parameter is a time duration that controls the minimum time at which the at least one feedback detector determines that a tone is a feedback signal and not an audio program signal.

40. The networked system of claim 37, further including at least one bandpass filter to eliminate a range of frequency components from the audio signal input to the feedback detector.

41. The apparatus of claim 40, wherein a user may adjust the range of frequency components eliminated.

42. The networked system of claim 37, wherein the user-adjustable input parameter of the feedback detector is a channel selection switch, such that the feedback detector operates only on input signals on a selected channel.

43. A method for the detection, identification and control of acoustic feedback tones in an audio system, comprising the steps of:
selecting at least one channel in an audio processing system for which feedback detection is desired;
filtering and summing audio signals from the selected channels to produce a composite audio signal;
searching, within the composite audio signal, for feedback tones, and if detected analyzing the composite audio signal to determine the characteristic of the feedback tones;
generating control signals and data indicating the characteristics of the feedback tones; and
displaying at least one of the characteristics in a human perceptible form.

44. The method of claim 43, further comprising the steps of:
processing at least one audio signal from the at least one selected channel in response to the control signals and data to suppress the feedback tones.

45. The method of claim 43, wherein the step of searching, within the composite audio signal, for feedback tones, includes receiving, user-adjustable input parameters for controlling the identification of feedback.)

46. The method of claim 45, wherein the user-adjustable input parameter specifies a threshold at which a tone is determined to be a feedback signal.

47. The method of claim 45, wherein the user-adjustable input parameter specifies the minimum time at which a tone is determined to be a feedback signal.

48. The method of claim 43, wherein the characteristics of the feedback tones are selected from the group consisting of:
input channel;
frequency;
amplitude; and
time duration.
